(19) United States
(12) Patent Application Publication
(10) Pub. No.: US 2025/0358980 A1
(43) Pub. Date: Nov. 20, 2025

(54) AUTOMATIC FLUID FLOW SWITCH FOR DATACENTERS

(71) Applicant: Intel Corporation, Santa Clara, CA (US)

(72) Inventors: Jeffrey Conner, Beaverton, OR (US); Christopher Gonzalez, Portland, OR (US)

(73) Assignee: Intel Corporation, Santa Clara, CA (US)

(21) Appl. No.: 19/284,165

(22) Filed: Jul. 29, 2025

(51) Int. Cl. H05K 7/20

(52) U.S. Cl. CPC H05K 7/2079

(57) ABSTRACT

A manifold for use in a datacenter. The manifold comprising a housing and a plunger positioned within the housing. The housing comprising an inlet for receiving a cooling fluid; an outlet for enabling an outflow of the cooling fluid; and a fluid flow passage for enabling the flow of the cooling fluid from the inlet to the outlet. The plunger including a fluid flow channel and a biasing member. The plunger moveable between first and second positions. In the first position, the fluid flow channel is misaligned with the fluid flow passage to prevent the cooling fluid from flowing from the inlet to the outlet. In the second position, the fluid flow channel is aligned with the fluid flow passage to permit the cooling fluid to flow from the inlet to the outlet. The biasing member automatically moves the plunger to the first position upon a loss of power.

### BACKGROUND

Advancements in technology and networking have led to the creation of large datacenters. A typical datacenter may include hundreds or thousands of nodes. For example, each datacenter may include hundreds or thousands of racks with each rack including hundreds of computing devices commonly referred to as nodes. The physical infrastructure can include a number of computing systems having processors, memory, storage, networking, power, cooling, etc. Management entities of these datacenters can aggregate a selection of the nodes to form servers and/or physical computing hosts. These hosts can subsequently be allocated to execute software system and host containers and/or applications. In use, uninterruptible power supply, generators, and sophisticated cooling systems are essential for reliable operations of datacenters.

### BRIEF DESCRIPTION OF THE SEVERAL VIEWS OF THE DRAWINGS

To easily identify the discussion of any particular element or act, the most significant digit or digits in a reference number refer to the figure number in which that element is first introduced.

FIG. 1A illustrates a perspective view of a manifold in accordance with one or more features of the present disclosure.

FIG. 1B is a detailed cross-sectional view of the manifold shown in FIG. 1A, the manifold including a plunger illustrated in a first or closed position.

FIG. 1C illustrates an alternate perspective view of the manifold shown in FIG. 1A, the plunger illustrated in a second or opened position.

FIG. 1D illustrates a cross-sectional view of the manifold shown in FIG. 1C.

FIGS. 1E and 1F illustrate various views of the manifold shown in FIG. 1A, the manifold including a pin to maintain the plunger in the second or opened position.

FIG. 2 illustrates a perspective view of a semiconductor package in accordance with one embodiment.

FIG. 3 illustrates a modular computing and cooling system in accordance with one embodiment.

FIG. 4 illustrates an electronic cooling cartridge in accordance with one embodiment.

FIG. 5 illustrates a system for an electronic cooling cartridge in accordance with one embodiment.

FIG. 6 illustrates a system for an electronic cooling cartridge in accordance with one embodiment.

FIG. 7 illustrates a system for an electronic cooling cartridge in accordance with one embodiment.

FIG. 8 illustrates a system for an electronic cooling cartridge in accordance with one embodiment.

FIG. 9 illustrates a system for an electronic cooling cartridge in accordance with one embodiment.

### DETAILED DESCRIPTION

Embodiments generally relate to an automated apparatus or device, system, and/or method to automatically prevent or stop the flow of a liquid, a fluid, a coolant, etc. (referred to herein a cooling fluid) upon the detection of a leak and/or deenergizing power to the effected node (e.g., rack, server blade, chassis, etc.). In one embodiment, the automated apparatus or device is a manifold arranged and configured to be positioned with a rack or blade within a rack.

Data centers are complex systems in which multiple technologies and pieces of hardware interact to maintain safe and continuous operation of servers. Generally speaking, data centers comprise a large number of racks that can contain numerous types of hardware or configurable resources (e.g., processing units, memory, storage, accelerators, networking, fans/cooling modules, power units, etc.). The types of hardware or configurable resources deployed in data centers may also be referred to as physical resources, platform devices, or nodes (terms used interchangeably herein without the intent to limit or distinguish). Terms being used generically to cover all types of computing resources such as, for examples, racks, servers, chassis, blades, etc. It is to be appreciated, that the size and number of nodes within a data center can be large, for example, on the order of hundreds of thousands of nodes. Furthermore, these nodes can be pooled to form virtual computing platforms for a large number and variety of computing tasks.

As noted, some of the nodes can be compute resources (e.g., central processing units, or the like) or accelerator resources (e.g., application specific integrated circuits, field-programmable gate arrays, or the like). Furthermore, the nodes include memory. Nodes may include resources of multiple types, such as—for example—processors, co-processors, accelerators, field-programmable gate arrays (FPGAs), graphics processing units (GPUs), memory, interconnect components, and storage. The embodiments are not limited to these examples.

Generally speaking, a data center includes a plurality of nodes, which may be arranged and configured as, or within, a plurality of racks with each rack including or housing a plurality of computing equipment (e.g., compute resources such as, for example, a chassis containing a sled or circuit boards or the like) (collectively referred to herein as “chassis”) interconnected by a multitude of cables and input/output connectors (I/O connectors). In use, the chassis houses components such as central processing units (CPUs), memory, and other components.

With so many systems requiring power, the electrical energy used generates thermal energy. As the data center operates, this heat builds and, unless removed, can cause equipment failures, system shutdowns, and physical damage to components. Much of this increased heat can be attributed to different processing units, collectively referred to as an “XPU,” where X stands for different letters depending on the context or specific function of the processing unit, which represents a shift towards more specialized, task-specific processors. Examples of an XPU include a central processing unit (CPU), graphics processing unit (GPU), data processing unit (DPU), vision processing unit (VPU), neural processing unit (NPU), infrastructure processing unit (IPU), tensor processing unit (TPU), and other processing units. Each new generation of XPU processor seems to offer greater speed, functionality, and storage, and chips are being asked to carry more of the load.

One challenge is providing sufficient cooling to data centers, which is both energy-efficient and scalable, with the ultimate goal of enabling greater compute and data storage in an energy-efficient context. Effective operation of any processor depends on temperatures remaining within designated thresholds. The more power an XPU uses, the hotter it becomes. When a component approaches its maximum temperature, a device may attempt to cool the processor by lowering its frequency or throttling it. Repeated or continuous throttling also reduces performance limiting the benefits of High Performance Computing (HPC) systems.

One such thermal management approach for cooling data centers is referred to as liquid cooling. Examples of liquid cooling techniques include direct liquid cooling, also known as direct-to-chip (DTC) cooling, and liquid immersion cooling. DTC cooling manages heat through the direct application of a cooling fluid onto the heat-generating components, such as processors and memory units. Unlike traditional air cooling that uses fans to circulate air around these components, direct liquid cooling involves circulating a coolant through a closed loop that absorbs heat directly from the components. This process significantly enhances cooling efficiency because liquids generally have higher heat capacity and conductivity than air. In direct liquid cooling systems, the coolant is pumped through cold plates that are in direct or indirect contact with the components. The heat from the components is transferred to the coolant. It is then circulated away and cooled through a heat exchanger. This method allows for more effective heat dissipation, enabling higher performance, increased component density, and potentially quieter operation due to the reduced need for fans. Direct liquid cooling is particularly beneficial in high-performance computing environments, like data centers and servers, as well as in high-end gaming personal computers and workstations, where the heat generated can exceed the capabilities of traditional air cooling methods.

In liquid immersion cooling systems, an immersion tank is filled with a dielectric fluid that partially or fully covers electronic components. The fluid dissipates heat generated by the electronic components. In open bath systems, an immersion tank is covered or uncovered and operates at atmospheric pressure. In closed bath systems, an immersion tank seals off the immersion fluid from the environment. The electronic components are fully submerged in a thermally conductive, electrically non-conductive liquid within a sealed enclosure. The closed bath immersion tank prevents the cooling fluid from coming into contact with the external environment. This enclosure helps in maintaining the integrity and cleanliness of the cooling fluid, preventing contamination and evaporation.

In either event, in use, generally speaking, each rack in a data center may include tubing for flowing cooling fluid throughout the rack to cool the nodes therein. In addition, each node (e.g., chassis) within a rack may include tubing for flowing cooling fluid internally throughout the node. Thus, generally speaking, each rack may include a manifold including an inlet for receiving tubing to carry fluid into the rack. In addition, each manifold may include one or more outlets for distributing the cooling fluid throughout the rack via tubing. For example, an outlet tube may be coupled to one of the nodes positioned within the rack. Similarly, each node may include a manifold including an inlet for receiving tubing to carry fluid into the node. In addition, each manifold may include one or more outlets for distributing the fluid throughout the node via tubing running internally within the node. Thus arranged, fluid flow can be used to cool the nodes.

Conventional liquid cooling systems suffer from various disadvantages. For example, if a cooling tube should leak, damage to adjacent components or nodes can be extensive. As a result, data centers have developed numerous industry solutions to detect leaks within the liquid cooling system. Currently, upon detection of a leak, electrical power to the node and/or the rack where the leak has been detected is terminated thereby powering the node and/or rack OFF. However, fluid continues to flow into the rack and/or node. In turn, this enables the fluid to continue to spread to other nodes within the rack until the fluid is eventually manually turned OFF by data center personnel such as, for example, by disconnecting the effected node and/or rack from the fluid tubes. Continued fluid flow puts additional nodes at risk. This risk is greater during weekends and after hours when reduced datacenter personnel are present.

Embodiments address these and other challenges using an automated apparatus or device (e.g., a manifold) to automatically prevent or stop the flow of cooling fluid upon the detection of a leak and/or deenergizing power to the effected node. Embodiments are generally directed to an improved manifold arranged and configured to automatically terminate the fluid flow upon termination of the electrical power to the effected node. That is, in accordance with one or more features of the present disclosure, upon detection of a leak and the termination of power to the effected node, the present disclosure provides a manifold arranged and configured to automatically terminate the fluid flow to the effected node. In some embodiments, as will be described in greater detail herein, the manifold includes a moveable plunger. In use, during normal operation, the plunger is in an opened position enabling fluid flow through the manifold. However, upon detection of a leak and subsequent termination of electric power to the node, the moveable plunger automatically moves from the opened position to a closed position preventing fluid flow through the manifold and into the node.

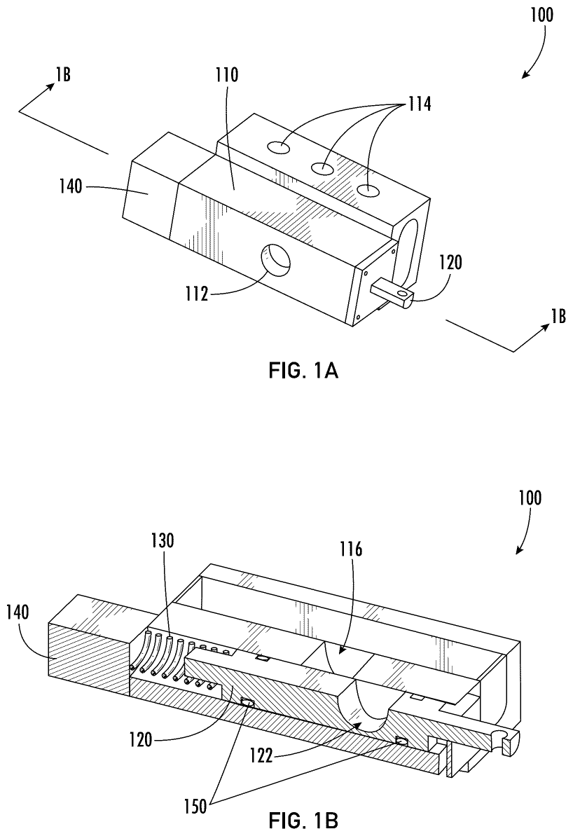

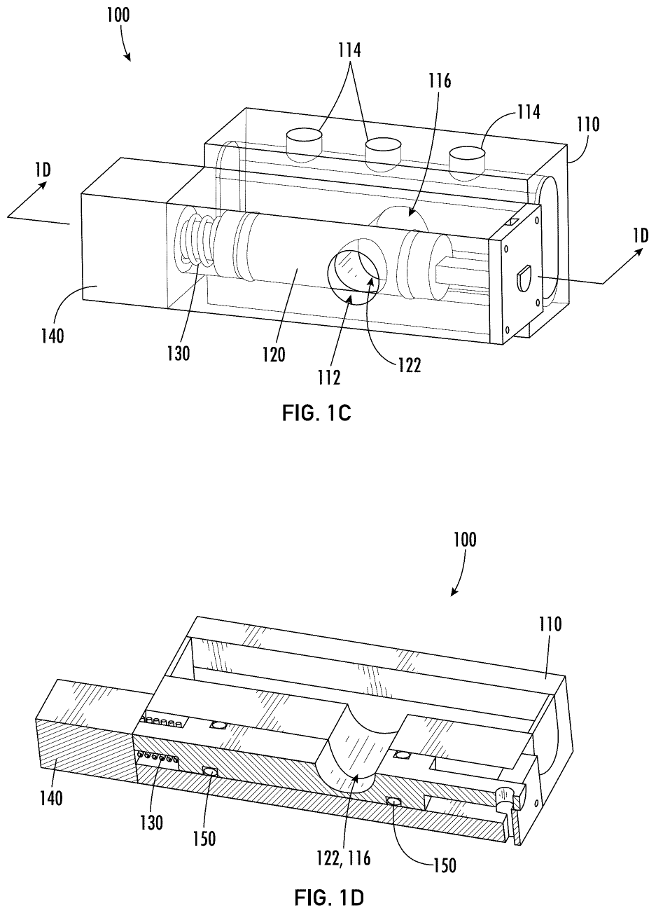

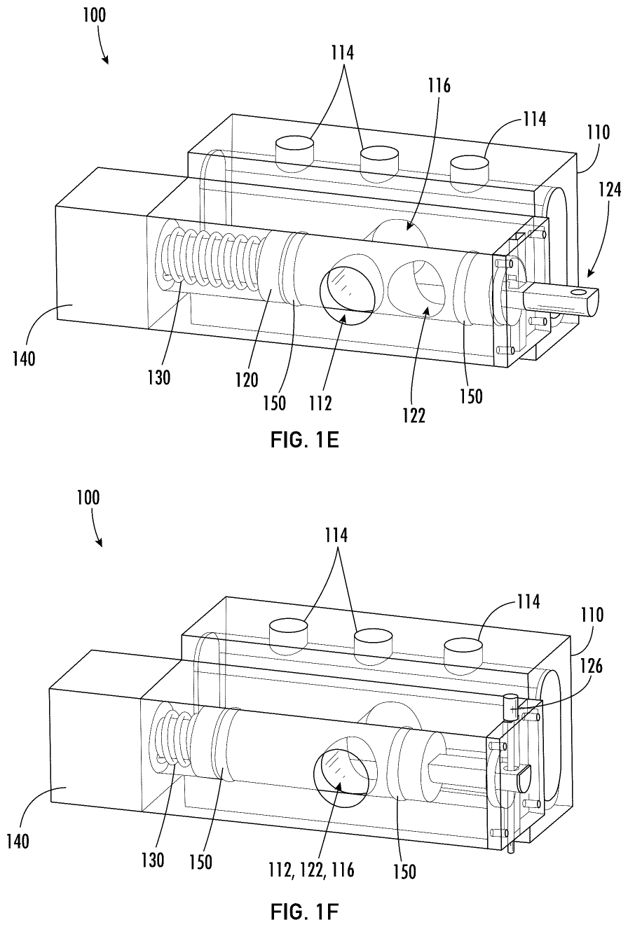

In accordance with one or more features of the present disclosure, with reference to FIGS. 1A-1F, an improved manifold 100 for use in a node such as, for example, a rack, a server blade, a chassis, etc., within a datacenter is disclosed. In use, the improved manifold 100 may be used in place of existing conventional manifolds used today within each node. Alternatively, the manifold 100 may be used in each rack to distribute fluid flow therethrough, or in any other suitable location.

As shown, the manifold 100 includes a housing 110 including an inlet 112 for receiving fluid flow via tubing, one or more outlets 114 for enabling the outflow of fluid via tubing, and a fluid flow passage 116 for enabling the flow of fluid from the inlet 112 to the outlet(s) 114. The manifold 100 including a plunger 120 moveable between a first or closed position (FIGS. 1A, 1B, and 1E) and a second or opened position (FIGS. 1C, 1D, and 1F). The plunger 120 including a fluid flow channel 122 defined or formed therein. In the first or closed position (FIGS. 1A, 1B, and 1E), the fluid flow channel 122 in the plunger 120 is misaligned (i.e., not aligned) with the fluid flow passage 116 in the housing 110 so that the flow of fluid from the inlet 112 to the outlet(s) 114 is prevented. In the second or opened position (FIGS. 1C, 1D, and 1F), the fluid flow channel 122 in the plunger 120 is aligned with the fluid flow passage 116 in the housing 110 so that the flow of fluid from the inlet 112 to the outlet(s) 114 is permitted.

In addition, as shown, the manifold 100 includes a biasing member 130 for biasing the plunger 120 to the first or closed position. The biasing member 130 can be any suitable member or mechanism now known or hereafter developed. In some embodiments, the biasing member 130 may be a spring such as, for example a coil spring. In addition, the manifold 100 includes a retention mechanism 140 arranged and configured to maintain the plunger 120 in the second or opened position when powered ON (i.e., when electrical power is supplied to the manifold 100). For example, in some embodiments, the manifold 100 may include an electromagnet, an electrical servo, or the like. In use, when power is supplied to the manifold 100, the retention mechanism 140 moves the plunger 120 from the first or closed position to the second or opened position. That is, the retention mechanism 140 moves the plunger 120 against the force of the biasing member 130. As such, in use, with electrical power supplied to the manifold 100, the plunger 120 is in the second or opened position with the fluid flow channel 122 formed in the plunger 120 aligned with the fluid flow passage 116 in the manifold 100. Thus aligned, fluid is permitted to flow from the inlet 112 through the fluid flow passage 116 in the housing 110 of the manifold 100 to the outlet(s) 114 where it can be distributed, via tubing, throughout the node.

However, in situations where a fluid flow leak is detected, power to the manifold 100 may be discontinued (e.g., the manifold 100 may be powered OFF). With no power to the manifold 100 (i.e., with the manifold deenergized), the retention mechanism 140 is no longer operational and the biasing member 130 biases or moves the plunger 120 from the second or opened position to the first or closed position (e.g., the retention mechanism 140 releases the plunger 120 allowing the biasing member 130 to bias or move the plunger 120 to the first or closed position). In the first or closed position, the fluid flow channel 122 in the plunger 120 is not aligned with the fluid flow passage 116 in the manifold 100. Thus, fluid is prevented from flowing from the inlet 112 to the outlet(s) 114 of the manifold 100.

In some embodiments, the manifold 100 may further include seals 150 on either side of the fluid flow channel 122 formed on the plunger 120 to prevent unwanted leakage. In use, the seals 150 may be any suitable seal now known or hereafter developed. For example, as shown, the seals 150 may be first and second O-rings positioned about the plunger 120.

In use, a system leak can be detected by any suitable mechanism or technique now known or hereafter developed. That is, as will be readily appreciated by one of ordinary skill in the art, numerous industry solutions have been developed to detect leaks within a liquid cooling system within a datacenter. Often times, upon detection of a leak, the leak detection system is arranged and configured to transmit one or more alerts. For example, in use, datacenters are continuously monitored by datacenter personnel. In addition, computer systems can be used or incorporated to monitor the status of the various components or nodes in the datacenter. One of these is a board management controller (BMC), which is a specialized microcontroller, which may be embedded on server motherboards. In use, the BMC monitors the health and status of various hardware components, including temperature, voltage, fan speeds, leaks, etc. In addition, the BMC may provide out-of-band management capabilities, allowing remote access, monitoring, and control of server hardware.

Upon detection of a leak via, for example, the BMC, electrical power to the effected node is terminated thereby powering OFF the node. In accordance with one or more features of the present disclosure, as previously discussed herein, powering OFF the node causes the plunger 120 to move from the second or opened position to the first or closed position, which causes fluid flow in the effected node to cease. Powering OFF the node causes the retention mechanism 140 to release the plunger 120. As a result, the biasing member 130 moves the plunger 120 from the second or opened position to the first or closed position. As a result, the fluid flow channel 122 in the plunger 120 is no longer aligned with the fluid flow passage 116 in the housing 110 of the manifold 100, which prevents fluid flow through the manifold 100 and into the node.

With reference to FIGS. 1E and 1F, in some embodiments, the plunger 120 may be configured to enable a user to maintain the plunger 120 in the second or opened position at all times. For example, as shown, the plunger 120 may include an opening 124 configured to receive a pin 126. In use, an end user may move the plunger 120 to the second or opened position and insert the pin 126 therethrough, which contacts the housing 110 and thus overcomes the biasing member 130 and maintains the plunger 120 in the second or opened position. This feature may be useful to, for example, maintain the plunger 120 in the second or opened position to facilitate draining or filling the node without power.

In use, the manifold 100 can be positioned anywhere within a node or data center within a liquid cooling system. For example, the manifold 100 can be used at the device level, rack level, system level, or any other suitable location within a datacenter or computing device. In some embodiments, as previously mentioned, the manifold 100 can be used in place of existing manifolds used within a platform device (e.g., a chassis, a blade server, etc.). Alternatively, the manifold 100 could be used within a rack to terminate fluid flow within the entire rack, or in other areas to terminate flow to one or more racks. As such, the present disclosure should not be limited to any particular use or area unless explicitly claimed.

For example, in one particularly preferred embodiment, one or more manifold(s) 100 may be used within one or more chassis or blade servers within a rack, referred to herein as a platform device. In use, the manifold 100 can be used in place of existing manifolds. In use, each chassis or blade server (e.g., platform device) may include one or more semiconductor packages.

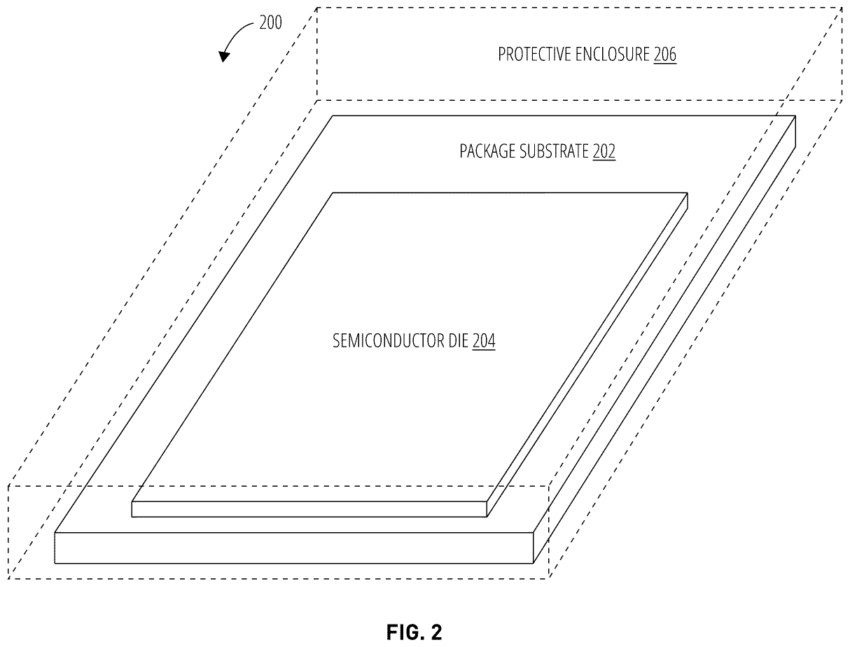

FIG. 2 is an example of a semiconductor package 200 suitable for use with an electronic cooling cartridge of a modular computing and cooling system as described herein. As depicted in FIG. 2, the semiconductor package 200 comprises core packaging components such as a package substrate 202 and one or more semiconductor dies 204 mounted on the package substrate 202, both of which are encapsulated by a protective enclosure 206. It is worthy to note that a semiconductor package 200 may include additional packaging components not shown in FIG. 2. For example, a semiconductor package 200 typically includes layers of conductive traces, electrical connectors, and support structures for the semiconductor die 204. These components are not shown for purposes of clarity and not limitation. Embodiments are not limited to the example shown in FIG. 2.

The semiconductor package 200 comprises a protective enclosure 206 for one or more semiconductor dies 204 mounted on a package substrate 202. The protective enclosure 206 provides electrical connections to external circuits and mechanical protection. It facilitates the integration of the semiconductor die 204 into larger electronic devices and circuit boards. The semiconductor package 200 also plays a role in heat dissipation, helping to remove the heat generated by the semiconductor die 204 and maintain optimal operating conditions. Examples of different types of semiconductor packages 200 include a Dual In-line Package (DIP), a Ball Grid Array (BGA), and a Quad Flat Package (QFP). Each semiconductor package 200 is designed to meet different requirements in terms of size, performance, and application. The choice of a semiconductor package 200 directly affects reliability, performance, cost, and size of an electronic device.

The package substrate 202 of the semiconductor package 200 acts as an intermediary platform between the semiconductor die 204 and external circuitry. An examples of package substrate 202 is a printed circuit board (PCB). It serves as a foundation on which the semiconductor die 204 is mounted and provides a pathway for electrical signals from the semiconductor die 204 to reach the external connections of the semiconductor package 200. The package substrate 202 is engineered from materials like ceramic, organic resin, or silicon, and it features multiple layers that include conductive traces and vias to facilitate electrical connectivity. These layers are meticulously designed to manage signal integrity, power distribution, and thermal performance. The package substrate 202 not only supports mechanical integrity and enhances the electrical performance of the semiconductor client device but also plays a vital role in heat dissipation, ensuring the longevity and reliability of the semiconductor die 204 by maintaining thermal conditions within operational limits. In one embodiment, the package substrate 202 is a PCB made of an FR-4 glass epoxy base with thin copper foil laminated on both sides. In some embodiments, the PCB is a multilayer PCB, with a pre-impregnated (pre-preg) layer and copper foil used to make additional layers. For example, the multilayer PCB may include one or more dielectric layers, where each dielectric layer can be a photosensitive dielectric layer. In some embodiments, holes may be drilled in the package substrate 202. The package substrate 202 may also include conductive layers that comprise conductive (or copper) traces, pads, vias, via pads, planes, and/or holes.

The semiconductor die 204 is a relatively small, thin piece of semiconductor material, typically silicon, which has been carefully fabricated to contain an integrated circuit (IC). The IC comprises numerous electronic components such as transistors, diodes, and resistors, all intricately patterned on the semiconductor substrate through processes like photolithography, etching, and doping. These components are interconnected to perform various electronic functions, ranging from simple logic operations to complex computational tasks. The semiconductor die 204 is encased in the protective enclosure 206 to form a complete electronic device, ensuring its functionality and reliability in a wide range of applications, including computers, smartphones, and various electronic systems. In an embodiment, the semiconductor die 204 may be implemented as a microprocessor, a microelectronic device, a semiconductor chip, a chiplet, an integrated circuit (IC), a circuit, a processor, processing circuitry, circuitry, an XPU, a controller, a platform controller hub (PCH), a memory, a field-programmable gate array (FPGA), power management IC, electronic control unit (ECU) for an autonomous vehicle, or any other semiconductor device.

Additionally, in some embodiments, thermal components such as a cold plate and a thermal interface material (TIM) layer may be disposed over the top surface of the semiconductor die 204 and/or the package substrate 202.

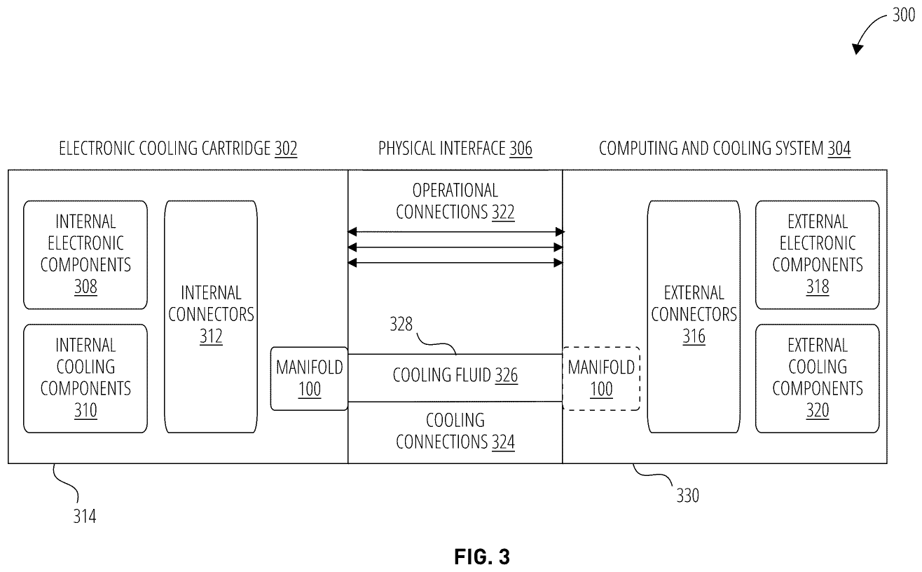

FIG. 3 illustrates a modular computing and cooling system 300. The modular computing and cooling system 300 is an example of a system implementing a modular computing and cooling architecture in accordance with various embodiments as described herein.

As previously described, embodiments are generally directed to a modular computing and cooling system 300 comprising one or more modular computing and cooling components designed for insertion and removal from a larger device or system, such as a personal computer (PC), platform device such as a server blade, system device such as a server rack in a data center, and so forth.

As depicted in FIG. 3, the modular computing and cooling system 300 comprises an electronic cooling cartridge 302 physically and operationally connected to a larger device or system, such as a computing and cooling system 304 by a physical interface 306. The electronic cooling cartridge 302 is a component of a larger computing and cooling system 304 comprising a system level cooling system for the electronic system. The electronic cooling cartridge 302 includes a combination of module level electronic components and module level cooling components. When a module level electronic component or a module level cooling component is in need of servicing to perform such tasks as equipment maintenance, repair, update, or replacement with upgraded equipment, the electronic cooling cartridge 302 is removed from the computing and cooling system 304. The serviced electronic cooling cartridge 302, or a replacement electronic cooling cartridge 302, is then re-inserted into the computing and cooling system 304 to resume operations.

The modular computing and cooling system 300 includes a physical interface 306 for the computing and cooling system 304. The physical interface 306 provides a set of operational connections 322 between the electronic cooling cartridge 302 and the computing and cooling system 304. The operational connections 322 communicate control and data signals between the electronic cooling cartridge 302 and the computing and cooling system 304. For the operational connections 322, the physical interface 306 utilizes various mediums to facilitate transmission of electrical signals or light signals, such as electrical connection mediums and optical connection mediums. Non-limiting examples of electrical connection mediums include copper wires or cables, twisted pair cables, coaxial cables, PCBs, traces, vias, and so forth. Non-limiting examples of optical connection mediums include fiber optic cables, plastic optical fibers, waveguides, free-space optical communications, and so forth. Both electrical and optical mediums have their specific applications, advantages, and limitations, chosen based on factors such as the required transmission speed, distance, cost, and environmental conditions. The physical interface 306 also provides a set of cooling connections 324 between the electronic cooling cartridge 302 and the computing and cooling system 304. The cooling connections 324 transport cooling fluid 326 between the electronic cooling cartridge 302 and the computing and cooling system 304. For the cooling connections 324, the physical interface 306 utilizes a fluid pipe to facilitate transport of the cooling fluid 326.

The computing and cooling system 304 comprises a chassis 330 housing a set of external electronic components 318 and a set of external cooling components 320. Non-limiting examples of external electronic components 318 include interfaces, controllers, buses, interconnect fabrics, input/output (I/O) components, platform components, system components, power supplies, batteries, and so forth. Non-limiting examples of external cooling components 320 include external fluid connectors, system level manifolds, fluid pipes to transport cooling fluid, cooling network units, cooling distribution units, fluid pumps, heat exchangers, condensers, and so forth. The external electronic components 318 and the external cooling components 320 are accessed via a set of external connectors 316 corresponding to similar connectors and media of the physical interface 306.

The modular computing and cooling system 300 also includes an electronic cooling cartridge 302 for insertion into the physical interface 306 and removal from the physical interface 306. The electronic cooling cartridge 302 includes a set of internal electronic components 308, a set of internal cooling components 310 for thermal management of the internal electronic components 308 using a cooling fluid, a set of internal connectors 312 to connect the internal electronic components 308 and the internal cooling components 310 to a set of external electronic components 318 and a set of external cooling components 320, respectively, of the computing and cooling system 304, and a closed container 314 encapsulating the set of internal electronic components 308, the set of internal cooling components 310, and the set of internal connectors 312.

In one embodiment, for example, an electronic cooling cartridge 302 comprises a closed container 314 encapsulating a combination of internal electronic components and internal cooling components. The closed container 314 is a hermetically sealed container that is completely airtight preventing the exchange of substances (e.g., liquids, solids, gases) between the inside of the closed container 314 and an external operating environment.

In one embodiment, for example, a set of internal electronic components 308 comprises internal connectors, semiconductor dies, semiconductor chips, integrated circuit components, processors, processing circuitry, XPUs, controllers, memory chips, chipsets, circuit boards, interconnects, buses, switching fabrics, power supplies, batteries, and so forth. In one embodiment, for example, a set of internal connectors 312 comprise connectors to connect the internal electronic components 308 with external electronic components 318 of the computing and cooling system 304, such as interfaces, controllers, buses, interconnect fabrics, input/output (I/O) components, platform components, system components, and so forth.

In one embodiment, for example, a set of internal cooling components 310 comprises internal fluid connectors, cold plates, fluid pipes to transport cooling fluid, manifolds, pumps, flow regulators, cooling units, cooling distribution units, heat exchangers, condensers, and so forth. In one embodiment, for example, a set of internal connectors 312 comprises a set of internal fluid connectors to connect internal cooling components 310 with external cooling components 320, such as external fluid connectors, system level manifolds, fluid pipes to transport cooling fluid, cooling network units, cooling distribution units, fluid pumps, heat exchangers, condensers, and so forth. The internal operation connectors and internal fluid connectors allow for insertion of the electronic cooling cartridge 302 into the larger computing and cooling system 304 and removal of the electronic cooling cartridge 302 from the larger computing and cooling system 304.

In addition, in some embodiments as illustrated, one or more manifolds 100 as previously described in connection with FIGS. 1A-1F, may be positioned on either side of a fluid pipe 328. In use, the manifold 100 receives and distributes the cooling fluid 326 as previously described. In addition, the one or more manifolds 100 are arranged and configured to automatically prevent the flow of cooling fluid upon termination of power to the manifold.

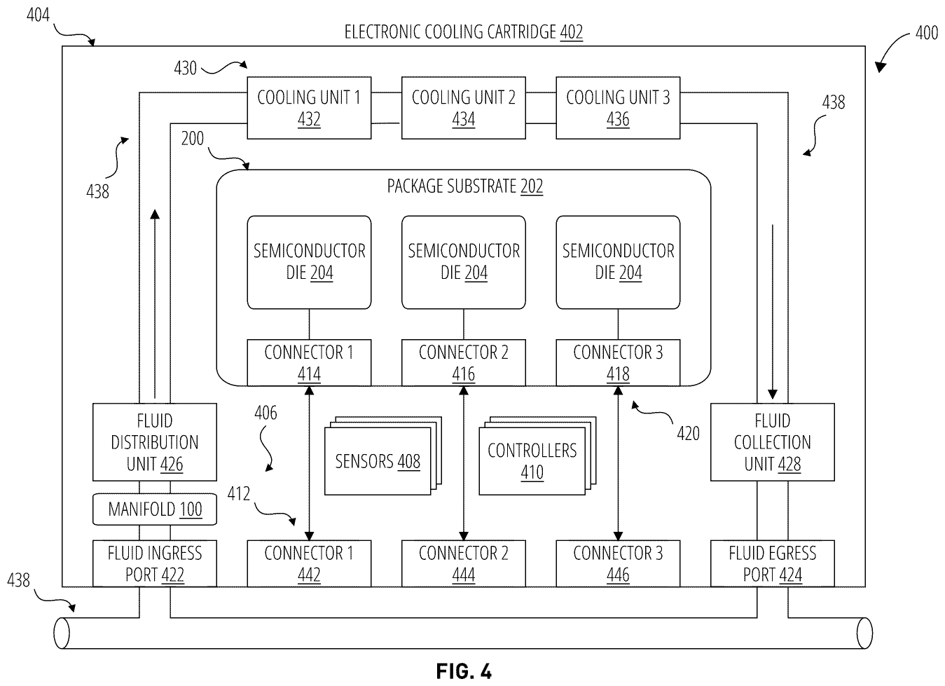

FIG. 4 illustrates an apparatus 400. The apparatus 400 comprises an example of an electronic cooling cartridge 402 suitable for use with the modular computing and cooling system 300. Specifically, the electronic cooling cartridge 402 comprises an example for the electronic cooling cartridge 302 implementing an N number of semiconductor dies 204 from the semiconductor package 200, with or without the protective enclosure 206, where N represents any positive integer. The electronic cooling cartridge 402 also comprises a set of internal electronic components 308 and a set of internal cooling components 310.

In some embodiments, one or more manifolds 100 may be positioned along fluid pipes 438. In use, the one or more manifold 100 receive and distribute the cooling fluid as previously described. In addition, the one or more manifolds 100 are arranged and configured to automatically prevent the flow of cooling fluid upon termination of power to the manifold.

As depicted in apparatus 400, the electronic cooling cartridge 402 comprises a closed container 404. In one embodiment, for example, the closed container 404 is a hermetically sealed container that is completely airtight preventing the exchange of substances (e.g., liquids, solids, gases) between the inside of the closed container and the external environment. The closed container 404 encapsulates a set of internal electronic components 308 and a set of internal cooling components 310 mounted on or proximate to a cartridge substrate 406. The cartridge substrate 406 may be implemented using the same or similar examples given for the package substrate 202 of the semiconductor package 200. In one embodiment, for example, the cartridge substrate 406 is a PCB.

The internal electronic components 308 may include a set of one or more controllers 410. The controllers 410 may control operations for one or more of the internal electronic components 308 and/or the internal cooling components 310. For example, the controllers 410 manage the operation of the cooling system to optimize performance and ensure efficient heat dissipation. It regulates various parameters of the liquid cooling system, such as pump speed to control the flow rate of the coolant to balance cooling efficiency and noise levels; fan speed to adjust the speed of fans attached to radiators or heat exchangers to control airflow and noise, based on the temperature of the coolant or the components being cooled; uses sensors 408 to monitor temperatures at critical points in the system, such as the liquid coolant, the radiator, and the components being cooled (like CPUs or GPUs); manage RGB lighting on components like fans, pumps, and reservoirs; and other management operations. The controllers 410 can operate based on system management commands or control directives, preset profiles, or dynamically adjust parameters of the cooling system in real-time based on feedback from sensors 408, achieving optimal cooling efficiency, noise levels, and power consumption. Some controllers 410 offer user interfaces, allowing users to customize settings according to their preferences or specific application requirements.

The internal electronic components 308 may include a set of one or more sensors 408 to monitor various properties and attributes of the internal electronic components and/or internal cooling components of the electronic cooling cartridge 402. In the liquid cooling system of the electronic cooling cartridge 402, various sensors 408 are employed to ensure efficient operation, safety, and performance monitoring. For example, the sensors 408 may include temperature sensors designed to measure the temperature of the liquid coolant and components being cooled, such as the semiconductor dies 204 and other electronic components. Common types of temperature sensors include thermocouples, thermistors, and resistance temperature detectors (RTDs). The sensors 408 may include flow sensors designed to measure a flow rate of the cooling fluid in the system, ensuring it is circulating properly. Examples include turbine flow sensors, ultrasonic flow sensors, and paddlewheel sensors. The sensors 408 may include pressure sensors designed to measure the pressure of the cooling fluid within the electronic cooling cartridge 402. This is important for detecting leaks, blockages, or pump failures. Common types include piezoelectric pressure sensors and strain gauge pressure sensors. The sensors 408 may include level sensors designed to detect a coolant level within a reservoir or tank, ensuring the system has enough cooling fluid to function properly. Types include capacitive level sensors, ultrasonic level sensors, and float level sensors. The sensors 408 may include pH sensors designed to monitor an acidity or alkalinity of the cooling fluid to prevent corrosion-related damage. The sensors 408 may include conductivity sensors designed to measure the electrical conductivity of the cooling fluid. This can be important for detecting contamination or the concentration of additives in the cooling fluid. The sensors may include temperature difference sensors designed to measure a temperature difference across the cooling system to assess its efficiency. Each of the sensors 408 plays a role in monitoring and controlling a liquid cooling system, contributing to its effectiveness and longevity. Embodiments are not limited to these examples.

The internal electronic components 308 may include the semiconductor package 200, such as the package substrate 202 and one or more semiconductor dies 204. In one embodiment, for example, the entire semiconductor package 200 is mounted on the cartridge substrate 406. In one embodiment, for example, only the package substrate 202 and the one or more semiconductor dies 204 are mounted on the cartridge substrate 406 without the protective enclosure 206. In one embodiment, for example, only the one or more semiconductor dies 204 are mounted on the cartridge substrate 406 without the package substrate 202 or the protective enclosure 206. Embodiments are not limited in this context.

The semiconductor package 200 further comprises a set of internal operation connectors, such as connectors 420, including a connector 1 414, a connector 2 416, and a connector 3 418 corresponding to a first semiconductor die 204, a second semiconductor die 204, and a third semiconductor die 204 (e.g., N=3), respectively. The connector 1 414, connector 2 416, and connector 3 418 correspond to a connector 1 442, a connector 2 444, and a connector 3 446, respectively, of the electronic cooling cartridge 402. The internal operation connectors attach to a set of physical wires or traces embedded in the package substrate 202 and/or the cartridge substrate 406 that provide a pathway for electrical and/or optical signals from the semiconductor dies 204 to reach external connections of the electronic cooling cartridge 402. Examples of connectors include electrical connectors, optical connectors, I/O connectors, power connectors, management connectors, and other types of connectors. Embodiments are not limited to these examples.

The closed container 404 further encapsulates a set of internal cooling components 310 mounted to the cartridge substrate 406. For example, the internal cooling components include a fluid ingress port 422, a fluid distribution unit 426, a fluid collection unit 428, a fluid egress port 424, a set of fluid pipes 438, and a set of cooling units 430. The cooling unit 430 may include a cooling unit 1 432, a cooling unit 2 434, and a cooling unit 3 436 for cooling the first semiconductor die 204, the second semiconductor die 204, and the third semiconductor die 204, respectively.

The fluid distribution unit 426 and the fluid collection unit 428 circulate the cooling fluid throughout the electronic cooling cartridge 402 along the liquid cooling path 312 through a set of fluid pipes 438. In various embodiments, the fluid pipes 438 may be partially or fully mounted on the cartridge substrate 406, embedded within the cartridge substrate 406, floating above the cartridge substrate 406, or some combination thereof. The fluid distribution unit 426 receives the cooling fluid from the fluid ingress port 422 and it distributes the cooling fluid to the cooling units 430 for collection by the fluid collection unit 428. The fluid collection unit 428 then sends the heated liquid to the fluid egress port 424 for thermal management by external cooling components 320 outside of the closed container 404 in an open-loop system. Additionally, or alternatively, the heated liquid can be re-circulated through internal thermal management components similar to the external cooling components 320 implemented as part of the closed container 404 in a closed-loop system. Embodiments are not limited in this context.

The fluid distribution unit 426 is a component designed to efficiently manage a flow and distribution of cooling fluid throughout the electronic cooling cartridge 402. This unit functions as a control center for the coolant movement, directing it from a cooling source, like a fluid ingress port 422 connected to a radiator or chiller, to the specific components that require cooling, such as the semiconductor dies 204. The fluid distribution unit 426 comprises one or more pumps to propel the cooling fluid, valves to control the flow direction of the cooling fluid, and channels or pathways that distribute the cooling fluid to various parts of the electronic cooling cartridge 402 while ensuring an even and optimal cooling effect. The fluid distribution unit 426 assists in maintaining a balance between the cooling capacity and a thermal load of the semiconductor dies 204 contained within the electronic cooling cartridge 402, thereby achieving efficient heat removal, minimizing temperature spikes, and ensuring the reliable operation of the semiconductor dies 204.

The fluid collection unit 428 is a component designed to gather and hold the cooling fluid after it has absorbed heat from the semiconductor dies 204. Once the cooling fluid circulates through the electronic cooling cartridge 402, absorbing heat from the hot components, it is directed towards the fluid collection unit 428. This unit acts as a reservoir, temporarily storing the heated fluid before it is directed to a cooling sink, such as a fluid egress port 424 connected to a cooling mechanism like a radiator or a heat exchanger to dissipate the absorbed heat to the surrounding environment before it is recirculated back through the electronic cooling cartridge 402. The fluid collection unit 428 ensures a consistent and uninterrupted flow of cooling fluid throughout the electronic cooling cartridge 402, helps in maintaining the optimal level of cooling fluid in the electronic cooling cartridge 402, and assists in managing thermal dynamics for the electronic cooling cartridge 402 by facilitating the efficient removal and recirculation of the cooling fluid. Its design ensures temperature stability and reliability of the semiconductor dies 204.

The fluid distribution unit 426 and/or the fluid collection unit 428 may be controlled by external commands received from a system management application via a management connector for the electronic cooling cartridge 402. For instance, a system operator or an automated system may generate command and control directives for the liquid cooling system of the electronic cooling cartridge 402 in response to measurements received from the one or more sensors 408. Examples of external commands include a set of control directives, such as a control directive to the fluid distribution unit 426 to release the cooling fluid from the fluid ingress port 422 into the fluid pipes 438, a control directive to the fluid collection unit 428 to drain the cooling fluid from the fluid pipes 438 to the fluid egress port 424, a control directive to control types of the cooling fluid to release into the fluid pipes 438 or drain from the fluid pipe 438, a control directive to control an amount of the cooling fluid to release into the fluid pipe 438 or draft from the fluid pipe 438, and other management operations for the cooling components of the electronic cooling cartridge 402.

The cooling unit 430 is a component designed to cool (or remove heat from) the semiconductor die 204. The cooling unit 430 may implement different types of liquid cooling techniques to cool the semiconductor die 204. Examples of liquid cooling techniques include direct liquid cooling and liquid immersion cooling.

In some embodiments, the cooling unit 430 may implement direct liquid cooling, also known as direct-to-chip (DTC) cooling, to manage heat through the direct application of a coolant liquid onto the heat-generating components, such as processors and memory units. In one embodiment, for example, the cooling unit 430 may implement direct die cooling which involves directly attaching a cooling block or cold plate 304 to the semiconductor die 204, as described with reference to FIG. 3. The cooling fluid flows directly over the semiconductor die 204, absorbing heat more efficiently than indirect methods. This technique ensures minimal thermal resistance between the semiconductor die 204 and the cooling fluid, providing effective cooling for high-power devices. In one embodiment, for example, the cooling unit 430 may implement microchannel cooling. Microchannel coolers are integrated into the semiconductor package 200 or directly onto the semiconductor die 204, featuring very narrow, micro-scale channels through which cooling fluid flows. This method increases the heat transfer surface area in contact with the semiconductor die 204, significantly enhancing heat removal from the semiconductor die 204. In one embodiment, for example, the cooling unit 430 may implement indirect liquid cooling. In this approach, the cooling fluid does not directly contact the semiconductor die 204. Instead, it circulates through a heat exchanger or cold plate attached to the package that houses the semiconductor die 204. While not as efficient as direct cooling methods, it offers a safer and cleaner option by reducing the risk of coolant leakage onto the semiconductor die 204.

In some embodiments, the cooling unit 430 may implement liquid immersion cooling which fills the closed container 404 with cooling fluid. The internal electronic components, such as the semiconductor dies 204, are partially or fully submerged in a thermally conductive, electrically non-conductive liquid within the closed container 404. The closed container 404 prevents the cooling fluid from coming into contact with the external environment. The closed container 404 helps in maintaining the integrity and cleanliness of the cooling fluid, preventing contamination and evaporation.

In one embodiment, for example, the 430 may implement jet impingement cooling. The cooling fluid is forcefully sprayed onto the semiconductor die 204 or its encapsulating package through nozzles, allowing for highly effective heat transfer. The impinging jets of cooling fluid enhance the cooling effect by actively removing heat from the surface of the semiconductor die 204, making it suitable for high-heat-flux applications.

In one embodiment, for example, the cooling unit 430 may implement a form of immersion cooling. The cooling unit 430 and/or the fluid distribution unit 426 may flood the entire closed container 404 with the cooling fluid to partially or completely immerse the semiconductor package 200 in the cooling fluid. For example, the cooling unit 430 and/or the fluid distribution unit 426 may have a valve to release the cooling fluid into the closed container 404 in response to a command from the system management application. Heat from the semiconductor die 204 is efficiently transferred to the surrounding liquid. This method is gaining popularity for cooling high-density computing hardware and offers the advantage of cooling multiple components simultaneously.

When the cooling unit 430 implements jet impingement cooling or liquid immersion cooling, the fluid collection unit 428 may periodically, or in response to a system management command, collect the cooling fluid from the closed container 404 via a pump or suction component from the electronic cooling cartridge 402 and send the collected cooling fluid to the fluid egress port 424.

The electronic cooling cartridge 402 may implement different types of cooling units 430, where each cooling unit 430 implements a liquid cooling technique that is tailored to the specific thermal management needs of the semiconductor dies 204, considering factors such as power density, size constraints, and reliability requirements of the semiconductor dies 204. Embodiments are not limited to these examples.

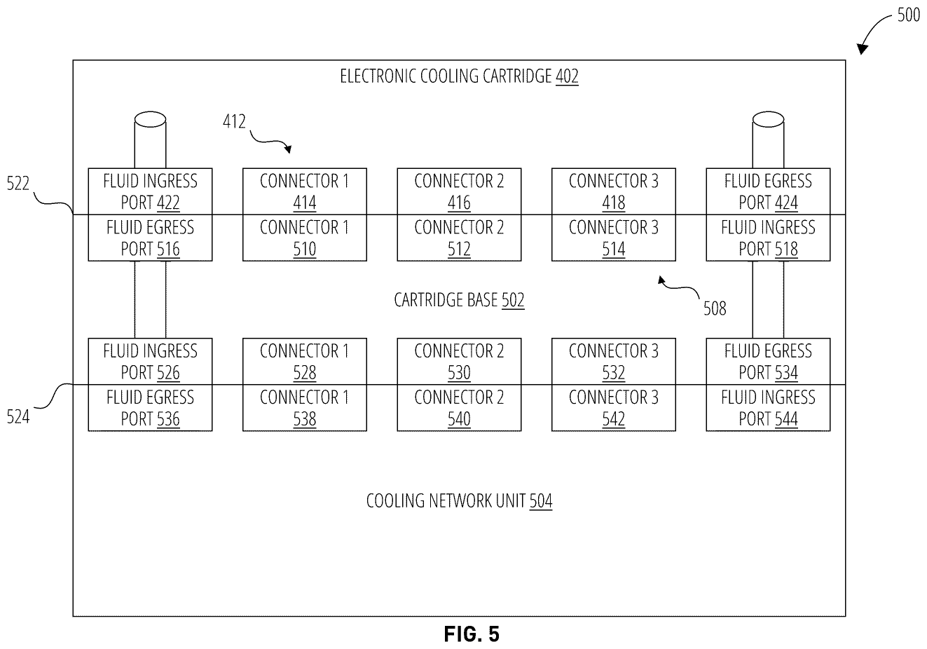

FIG. 5 illustrates a system 500. The system 500 comprises an example implementation for the electronic cooling cartridge 402 connected to an external liquid cooling system of a larger device, platform, or system.

As depicted in FIG. 5, the system 500 comprises an electronic cooling cartridge 402 physically and operably coupled to a cartridge base 502. The cartridge base 502 operates as intermediate component between the electronic cooling cartridge 402 and a cooling network unit 504 of an external device, platform, or system. The cartridge base 502 incorporates various interface components to connect the internal electronic components and internal cooling components with corresponding external electronic components and external cooling components of the cooling network unit 504. For example, the internal operation connectors of the electronic cooling cartridge 402 such as the connector 1 414, the connector 2 416, and the connector 3 418 correspond to external operation connectors such as a connector 1 510, a connector 2 512, and a connector 3 514, respectively, of the cartridge base 502. Similarly, the internal cooling connectors of the electronic cooling cartridge 402 such as the fluid ingress port 422 and the fluid egress port 424 correspond to external fluid connectors such as a fluid egress port 516 and a fluid ingress port 518, respectively, of the cartridge base 502. The external operation connectors such as connector 1 510, connector 2 512, and connector 3 514 of the cartridge base 502 correspond to a connector 1 538, a connector 2 540, and a connector 3 542, respectively, of the cooling network unit 504. Similarly, the external fluid connectors such as fluid ingress port 526 and the fluid egress port 534 of the cartridge base 502 correspond to a fluid egress port 536 and a fluid ingress port 544, respectively, of the cooling network unit 504.

The cartridge base 502 also has a form factor with a physical size, geometry, and interfaces that match those of the electronic cooling cartridge 402 on side A 522 of the cartridge base 502, as well as the cooling network unit 504 on side B 524 of the cartridge base 502. When the electronic cooling cartridge 402 has a different form factor or interfaces from those used by the cooling network unit 504 of the larger device or system, a cartridge base 502 is selected to match the electronic cooling cartridge 402 and the cooling network unit 504 to ensure physical and operational connections between the electronic cooling cartridge 402 and the cooling network unit 504 of the larger device or system, and vice-versa. The configurability of the cartridge base 502 allows electronic cooling cartridges 402 from one original equipment manufacturer (OEM) to interoperate with devices and systems from another OEM, and vice-versa, thereby offering flexibility to different OEMs and liquid cooling technology developers and providers.

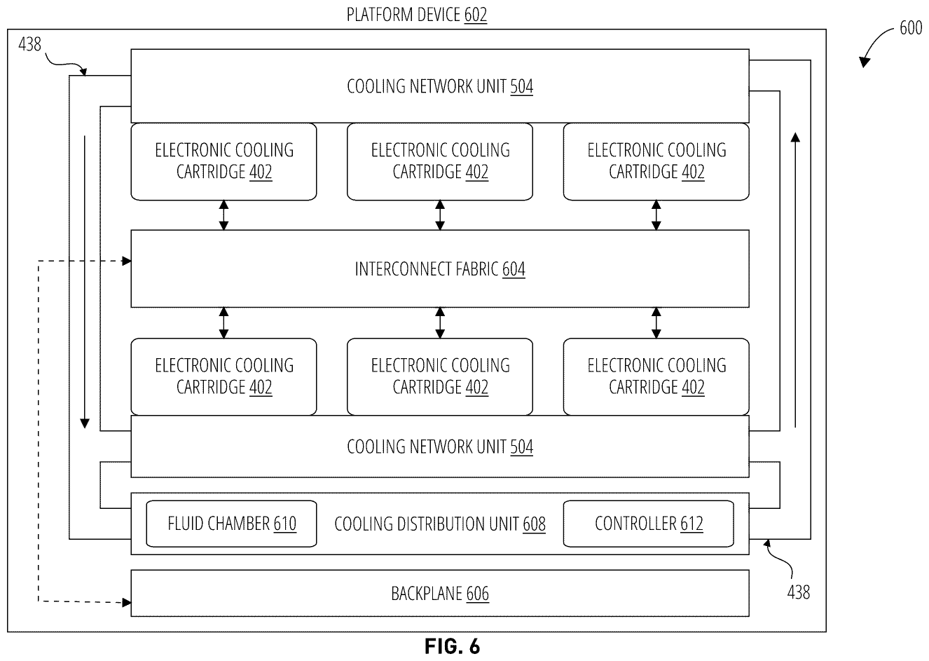

FIG. 6 illustrates a system 600 suitable for the semiconductor package 200, the apparatus 400, and the system 500. The system 600 comprises an example of a platform device 602 comprising a C number of electronic cooling cartridges 402 implemented as part of a larger platform or system, where C represents any positive integer.

As depicted in FIG. 6, the system 600 comprises a platform device 602 for a larger device, such as a server blade of a server system of a data center, for example. The platform device 602 comprises six electronic cooling cartridges 402 (C=6). The electronic cooling cartridges 402 interface with the cooling network units 504 using various cartridge bases 502 as described with reference to FIG. 5. The electronic cooling cartridges 402 also connect to an interconnect fabric 604 and a cooling distribution unit 608. The interconnect fabric 604 connects to a backplane 606.

The electronic cooling cartridges 402 connect to the interconnect fabric 604. The interconnect fabric 604 is a high-speed communication infrastructure that allows the electronic cooling cartridges 402 within the platform device 602 to communicate with each other and with external networks and devices. The interconnect fabric 604 enables data, control, and management traffic to flow between the electronic cooling cartridges 402 and also between the platform device 602 and a larger server system and other parts of a data center infrastructure via the backplane 606, such as a Peripheral Component Interconnect (PCIe) backplane 606, for example. The interconnect fabric 604 includes both hardware and software components. The hardware components includes the physical pathways for data transmission such as backplane connectors, cables, switches, and other networking hardware integrated within the platform device 602. These components are designed to provide high bandwidth and low latency connections. The software components encompass the protocols, interfaces, and management tools that facilitate communication over the hardware infrastructure. This software layer enables efficient data routing, security, and network configuration and troubleshooting. The design of the interconnect fabric 604 can vary based on a server model and the specific requirements of the data center, but its primary goal is to ensure robust, scalable, and flexible connectivity for all electronic cooling cartridges 402 within the platform device 602. This enables the electronic cooling cartridges 402 to operate cohesively as part of a larger computing resource, optimizing performance and reliability in processing, storage, and communication tasks.

The electronic cooling cartridges 402 connect to the cooling distribution unit 608 via one or more fluid pipes 438. The cooling distribution unit 608 in a liquid cooling system is a component designed to distribute the cooling fluid stored in a fluid chamber 610 to multiple cooling points within the platform device 602. The cooling distribution unit 608 manages and maintains the efficiency of the cooling process. The cooling distribution unit 608 serves various functions. For example, the cooling distribution unit 608 performs a temperature regulation function. The cooling distribution unit 608 ensures that the cooling fluid is at the correct temperature before it is circulated through the system. This involves cooling the liquid if it has warmed up after absorbing heat from the system components. The cooling distribution unit 608 performs a flow control function. It regulates the flow rate of the cooling fluid to the various parts of the platform device 602 that require cooling, ensuring optimal heat exchange and system performance. The cooling distribution unit 608 can adjust the flow dynamically based on temperature readings and cooling demand from a set of sensors 408 internal to the electronic cooling cartridges 402 or implemented as part of the platform device 602. The cooling distribution unit 608 perform a pressure maintenance function. The cooling distribution unit 608 helps maintain the proper pressure within the cooling system, ensuring that the cooling fluid circulates effectively without causing leaks or damage to the system components. The cooling distribution unit 608 performs a filtration function. The cooling distribution unit 608 may incorporate filters to remove particulates from the cooling fluid, thus preventing clogging and ensuring the longevity and efficiency of the cooling system. The cooling distribution unit 608 performs a deaeration function. The cooling distribution unit 608 may remove air bubbles from the cooling fluid. Air bubbles can reduce the effectiveness of heat transfer and lead to noise and vibration in the system. The cooling distribution unit 608 performs a coolant distribution function. The cooling distribution unit 608 directs the cooling fluid to specific components or areas needing cooling, such as computer processors, power supplies, or electric vehicle battery packs, and then returns the warmed liquid back to the cooling system for re-cooling. The cooling distribution unit 608 is an important part of both small-scale and large-scale liquid cooling setups, including data center cooling systems, industrial process cooling, and cooling systems for high-performance computing and electronics. They contribute to system efficiency by ensuring that cooling resources are used optimally.

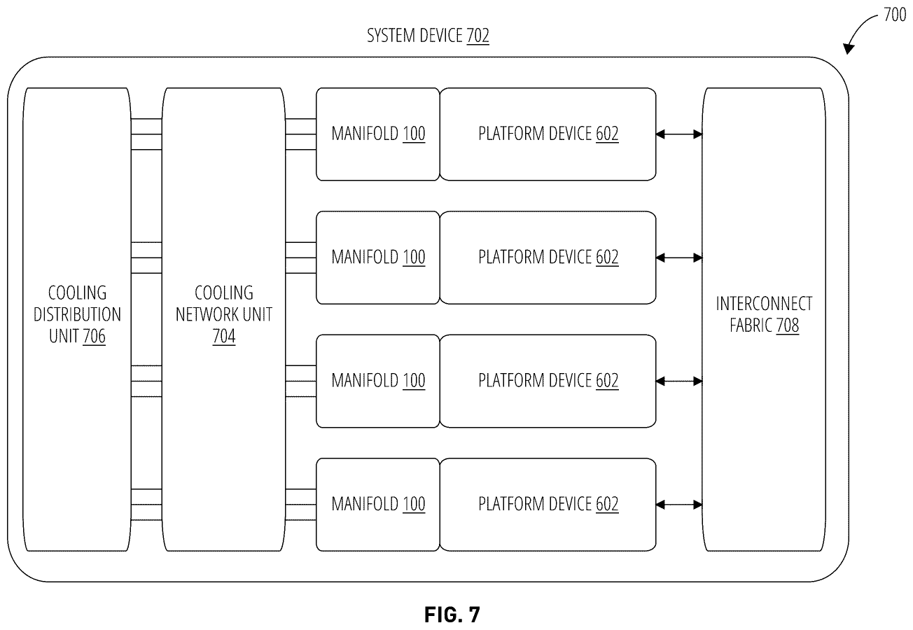

FIG. 7 illustrates a system 700. The system 700 comprises an example of a system device 702 comprising a P number of platform devices 602 implemented as part of a larger system, where P represents any positive integer.

As depicted in FIG. 7, the system 700 comprises a system device 702 for a larger system, such as a server rack or server system of a data center, for example. As shown, the system device 702 comprises four platform devices 602 (P=4). Each of the platform devices 602 interfaces with a cooling network unit 704, which is a system level version of the cooling network units 504 as described with reference to FIG. 5. The platform devices 602 also connect to an interconnect fabric 708, which is a system level version of the interconnect fabric 604, via the backplanes 606 of the platform devices 602. The platform devices 602 also connect to a cooling distribution unit 706, which is a system level version of the cooling distribution unit 608.

As illustrated, in some embodiments, one or more manifolds 100 may be positioned in fluid communication with one or more of the platform devices 602. In use, the one or more manifolds 100 receive cooling fluid from the cooling network unit 704 for distribution to the various components within each platform device 602 as previously described. In addition, the one or more manifolds 100 are arranged and configured to automatically prevent the flow of cooling fluid upon termination of power to the manifold.

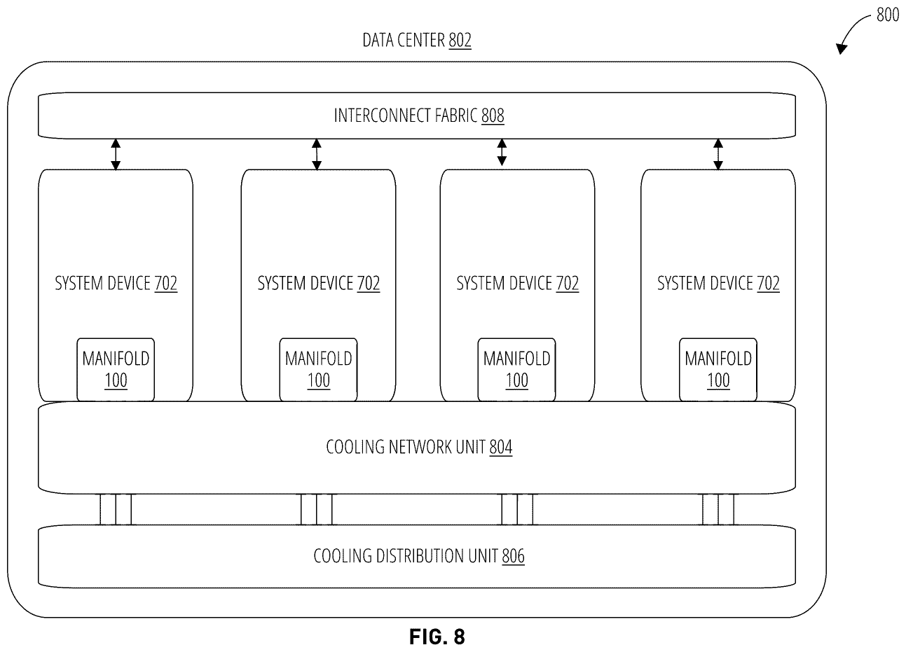

FIG. 8 illustrates a system 800. The system 800 comprises an example of a data center 802 comprising an S number of system devices 702 implemented as part of a larger system, where S represents any positive integer.

As depicted in FIG. 8, the system 800 comprises system devices 702 for a larger system, such as a data center 802, for example. As shown, the data center 802 comprises four system device 702 (S=4). Each of the system devices 702 interfaces with a cooling network unit 804, which is a data center level version of the cooling network units 504 as described with reference to FIG. 5. The system devices 702 also connect to an interconnect fabric 808, which is a data center level version of the interconnect fabric 604, via the interconnect fabric 708 of the system devices 702. The system devices 702 also connects to a cooling distribution unit 806, which is a data center level version of the cooling distribution unit 608 and/or cooling distribution unit 706.

As illustrated, in some embodiments, one or more manifolds 100 may be positioned in each system device 702. In use, the one or more manifolds 100 receive cooling fluid from the cooling network unit 804 for distribution to the various components within each system device 702 as previously described. In addition, the one or more manifolds 100 are arranged and configured to automatically prevent the flow of cooling fluid upon termination of power to the manifold.

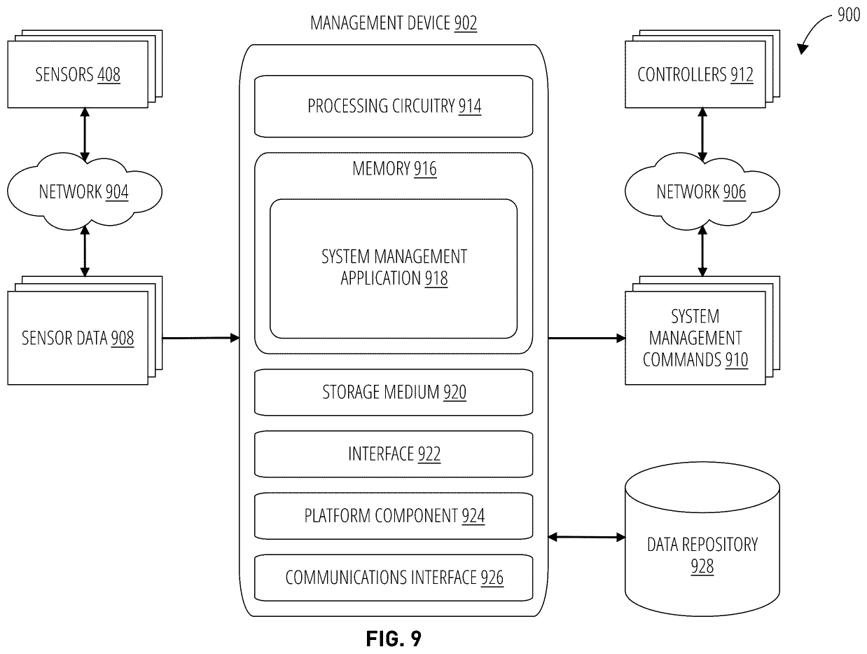

FIG. 9 illustrates an embodiment of a system 900. The system 900 is suitable for implementing one or more embodiments as described herein. In one embodiment, for example, the system 900 implements a management device 902 for receiving and decoding sensor data 908 from one or more sensors 408 of the apparatus 400, the system 500, the system 600, the system 700, and/or the system 800, analyzing the sensor data 908, and sending and encoding one or more system management commands 910 to the apparatus 400, the system 500, the system 600, the system 700, and/or the system 800.

The system 900 comprises a set of M devices, where M is any positive integer. FIG. 9 depicts three devices (M=3), including a set of sensors 408, a management device 902, and a set of controllers 912. The management device 902 communicates information with the sensors 408 and the controllers 912 over a network 904 and a network 906, respectively. The information may include sensor data 908 from the sensors 408 and system management commands 910 to the controllers 912.

As depicted in FIG. 9, the management device 902 includes processing circuitry 914, a memory 916, a storage medium 920, an interface 922, and a platform component 924. In some implementations, the management device 902 includes other components or devices as well.

The management device 902 is generally arranged to receive sensor data 908, process the sensor data 908 via one or more analysis techniques, and send system management commands 910. The management device 902 receives the sensor data 908 from the sensors 408 via the network 904. The management device 902 sends the system management commands 910 to the controllers 912 via the network 906, the platform component 924 (e.g., a touchscreen as a text command or microphone as a voice command), the system management application 918, the memory 916, the storage medium 920, or the data repository 928.

In one embodiment, the controllers 912 control various internal electronic components and/or internal cooling components of the electronic cooling cartridge 402. For example, the fluid distribution unit 426 and/or the fluid collection unit 428 may be controlled by system management commands 910 received from the system management application 918 via a management connector for the electronic cooling cartridge 402. For instance, a system operator or an automated system may use the system management application 918 to generate command and control directives for the liquid cooling system of the electronic cooling cartridge 402 in response to measurements received from the one or more sensors 408. Examples of system management commands 910 include a set of control directives, such as a control directive to the fluid distribution unit 426 to release the cooling fluid from the fluid ingress port 422 into the fluid pipes 438, a control directive to the fluid collection unit 428 to drain the cooling fluid from the fluid pipes 438 to the fluid egress port 424, a control directive to control types of the cooling fluid to release into the fluid pipes 438 or drain from the fluid pipe 438, a control directive to control an amount of the cooling fluid to release into the fluid pipe 438 or draft from the fluid pipe 438, and other management operations for the cooling components of the electronic cooling cartridge 402.

In one embodiment, for example, the system management application 918 may instruct the electronic cooling cartridge 402 to use different cooling techniques, such as a hybrid cooling technique combining the use of cold plates and different types of cooling fluids depending on thermal design power (TDP) requirements and environmental conditions supporting different climate conditions. For instance, a data center located in colder climates would require less cooling relative to a data center located in warmer climates that require more cooling. Further, some locations may shift between a colder climate and a warmer climate on a seasonal basis, thereby necessitating different electronic cooling modules with different cooling liquids during different seasons in a given year. To service an electronic cooling cartridge housing the semiconductor dies 204, such as an XPU, the XPU is powered down, the cooling fluid is pumped out of the fluid pipes 438 and/or the closed container 404, and it is ready for safe removal from the platform device 602 or the system device 702. For reinsertion, a system operator can insert the electronic cooling cartridge 402 with the empty closed container 404 into the platform device 602 or the system device 702, access the system management application 918 to select a cooling fluid for the empty closed container 404. A fluid pump from a cooling distribution unit, such as the cooling distribution unit 506, the cooling distribution unit 608, cooling distribution unit 706, or the cooling distribution unit 806, moves the liquid into the internal cooling components of the electronic cooling cartridge 402, and the system powers on the XPU to become operational once again. Embodiments are not limited to these examples.

The various elements of the devices as previously described with reference to the figures include various hardware elements, software elements, or a combination of both. Examples of hardware elements include devices, logic devices, components, processors, microprocessors, circuits, processors, circuit elements (e.g., transistors, resistors, capacitors, inductors, and so forth), integrated circuits, application specific integrated circuits (ASIC), programmable logic devices (PLD), digital signal processors (DSP), field programmable gate array (FPGA), memory units, logic gates, registers, semiconductor device, chips, microchips, chip sets, and so forth. Examples of software elements include software components, programs, applications, computer programs, application programs, system programs, software development programs, machine programs, operating system software, middleware, firmware, software modules, routines, subroutines, functions, methods, procedures, software interfaces, application program interfaces (API), instruction sets, computing code, computer code, code segments, computer code segments, words, values, symbols, or any combination thereof. However, determining whether an embodiment is implemented using hardware elements and/or software elements varies in accordance with any number of factors, such as desired computational rate, power levels, heat tolerances, processing cycle budget, input data rates, output data rates, memory resources, data bus speeds and other design or performance constraints, as desired for a given implementation.

One or more aspects of at least one embodiment are implemented by representative instructions stored on a machine-readable medium which represents various logic within the processor, which when read by a machine causes the machine to fabricate logic to perform the techniques described herein. Such representations, known as “intellectual property (IP) cores” are stored on a tangible, machine readable medium and supplied to various customers or manufacturing facilities to load into the fabrication machines that make the logic or processor. Some embodiments are implemented, for example, using a machine-readable medium or article which may store an instruction or a set of instructions that, when executed by a machine, causes the machine to perform a method and/or operations in accordance with the embodiments. Such a machine includes, for example, any suitable processing platform, computing platform, computing device, processing device, computing system, processing system, processing devices, computer, processor, or the like, and is implemented using any suitable combination of hardware and/or software. The machine-readable medium or article includes, for example, any suitable type of memory unit, memory device, memory article, memory medium, storage device, storage article, storage medium and/or storage unit, for example, memory, removable or non-removable media, erasable or non-erasable media, writeable or re-writeable media, digital or analog media, hard disk, floppy disk, Compact Disk Read Only Memory (CD-ROM), Compact Disk Recordable (CD-R), Compact Disk Rewriteable (CD-RW), optical disk, magnetic media, magneto-optical media, removable memory cards or disks, various types of Digital Versatile Disk (DVD), a tape, a cassette, or the like. The instructions include any suitable type of code, such as source code, compiled code, interpreted code, executable code, static code, dynamic code, encrypted code, and the like, implemented using any suitable high-level, low-level, object-oriented, visual, compiled and/or interpreted programming language.

As utilized herein, terms “component,” “system,” “interface,” and the like are intended to refer to a computer-related entity, hardware, software (e.g., in execution), and/or firmware. For example, a component is a processor (e.g., a microprocessor, a controller, or other processing device), a process running on a processor, a controller, an object, an executable, a program, a storage device, a computer, a tablet PC and/or a user equipment (e.g., mobile phone, etc.) with a processing device. By way of illustration, an application running on a server and the server is also a component. One or more components reside within a process, and a component is localized on one computer and/or distributed between two or more computers. A set of elements or a set of other components are described herein, in which the term “set” can be interpreted as “one or more.”

Further, these components execute from various computer readable storage media having various data structures stored thereon such as with a module, for example. The components communicate via local and/or remote processes such as in accordance with a signal having one or more data packets (e.g., data from one component interacting with another component in a local system, distributed system, and/or across a network, such as, the Internet, a local area network, a wide area network, or similar network with other systems via the signal).

As another example, a component is an apparatus with specific functionality provided by mechanical parts operated by electric or electronic circuitry, in which the electric or electronic circuitry is operated by a software application or a firmware application executed by one or more processors. The one or more processors are internal or external to the apparatus and execute at least a part of the software or firmware application. As yet another example, a component is an apparatus that provides specific functionality through electronic components without mechanical parts; the electronic components include one or more processors therein to execute software and/or firmware that confer(s), at least in part, the functionality of the electronic components.

Use of the word exemplary is intended to present concepts in a concrete fashion. As used in this application, the term “or” is intended to mean an inclusive “or” rather than an exclusive “or”. That is, unless specified otherwise, or clear from context, “X employs A or B” is intended to mean any of the natural inclusive permutations. That is, if X employs A; X employs B; or X employs both A and B, then “X employs A or B” is satisfied under any of the foregoing instances. In addition, the articles “a” and “an” as used in this application and the appended claims should generally be construed to mean “one or more” unless specified otherwise or clear from context to be directed to a singular form. Furthermore, to the extent that the terms “including”, “includes”, “having”, “has”, “with”, or variants thereof are used in either the detailed description or the claims, such terms are intended to be inclusive in a manner similar to the term “comprising.” Additionally, in situations wherein one or more numbered items are discussed (e.g., a “first X”, a “second X”, etc.), in general the one or more numbered items may be distinct or they may be the same, although in some situations the context may indicate that they are distinct or that they are the same.

As used herein, the term “circuitry” may refer to, be part of, or include a circuit, an integrated circuit (IC), a monolithic IC, a discrete circuit, a hybrid integrated circuit (HIC), an Application Specific Integrated Circuit (ASIC), an electronic circuit, a logic circuit, a microcircuit, a hybrid circuit, a microchip, a chip, a chiplet, a chipset, a multi-chip module (MCM), a semiconductor die, a system on a chip (SoC), a processor (shared, dedicated, or group), a processor circuit, a processing circuit, or associated memory (shared, dedicated, or group) operably coupled to the circuitry that execute one or more software or firmware programs, a combinational logic circuit, or other suitable hardware components that provide the described functionality. In some embodiments, the circuitry is implemented in, or functions associated with the circuitry are implemented by, one or more software or firmware modules. In some embodiments, circuitry includes logic, at least partially operable in hardware. It is noted that hardware, firmware and/or software elements may be collectively or individually referred to herein as “logic” or “circuit.”

Some embodiments are described using the expression “one embodiment” or “an embodiment” along with their derivatives. These terms mean that a particular feature, structure, or characteristic described in connection with the embodiment is included in at least one embodiment. The appearances of the phrase “in one embodiment” in various places in the specification are not necessarily all referring to the same embodiment. Moreover, unless otherwise noted the features described above are recognized to be usable together in any combination. Thus, any features discussed separately can be employed in combination with each other unless it is noted that the features are incompatible with each other.

Some embodiments are presented in terms of program procedures executed on a computer or network of computers. A procedure is here, and generally, conceived to be a self-consistent sequence of operations leading to a desired result. These operations are those requiring physical manipulations of physical quantities. Usually, though not necessarily, these quantities take the form of electrical, magnetic or optical signals capable of being stored, transferred, combined, compared, and otherwise manipulated. It proves convenient at times, principally for reasons of common usage, to refer to these signals as bits, values, elements, symbols, characters, terms, numbers, or the like. It should be noted, however, that all of these and similar terms are to be associated with the appropriate physical quantities and are merely convenient labels applied to those quantities.

Further, the manipulations performed are often referred to in terms, such as adding or comparing, which are commonly associated with mental operations performed by a human operator. No such capability of a human operator is necessary, or desirable in most cases, in any of the operations described herein, which form part of one or more embodiments. Rather, the operations are machine operations. Useful machines for performing operations of various embodiments include general purpose digital computers or similar devices.

Some embodiments are described using the expression “coupled” and “connected” along with their derivatives. These terms are not necessarily intended as synonyms for each other. For example, some embodiments are described using the terms “connected” and/or “coupled” to indicate that two or more elements are in direct physical or electrical contact with each other. The term “coupled,” however, also means that two or more elements are not in direct contact with each other, but yet still co-operate or interact with each other.

Various embodiments also relate to apparatus or systems for performing these operations. This apparatus is specially constructed for the required purpose or it comprises a general purpose computer as selectively activated or reconfigured by a computer program stored in the computer. The procedures presented herein are not inherently related to a particular computer or other apparatus. Various general purpose machines are used with programs written in accordance with the teachings herein, or it proves convenient to construct more specialized apparatus to perform the required method steps. The required structure for a variety of these machines are apparent from the description given.

It is emphasized that the Abstract of the Disclosure is provided to allow a reader to quickly ascertain the nature of the technical disclosure. It is submitted with the understanding that it will not be used to interpret or limit the scope or meaning of the claims. In addition, the following claims are hereby incorporated into the Detailed Description, with each claim standing on its own as a separate embodiment. In the appended claims, the terms “including” and “in which” are used as the plain-English equivalents of the respective terms “comprising” and “wherein,” respectively. Moreover, the terms “first,” “second,” “third,” and so forth, are used merely as labels, and are not intended to impose numerical requirements on their objects.

The following examples pertain to further embodiments, from which numerous permutations and configurations will be apparent.

Example 1. An apparatus, comprising a manifold for a node of a datacenter, the manifold comprising a housing and a plunger positioned within the housing, the housing comprising an inlet for receiving an inflow of a cooling fluid via tubing; an outlet for enabling an outflow of the cooling fluid via tubing; and a fluid flow passage for enabling the flow of the cooling fluid from the inlet to the outlet; and the plunger including a fluid flow channel and a biasing member, the plunger moveable between a first position and a second position, wherein in the first position, the fluid flow channel in the plunger is misaligned with the fluid flow passage in the housing to prevent the flow of the cooling fluid from the inlet to the outlet; in the second position, the fluid flow channel in the plunger is aligned with the fluid flow passage in the housing to permit the flow of the cooling fluid from the inlet to the outlet; and the biasing member automatically moves the plunger from the second position to the first position to prevent the flow of liquid upon a loss of power.

Example 2. The apparatus of example 1, wherein the biasing member biases the plunger to the first position.

Example 3. The apparatus of claim 1, wherein the biasing member is a spring.

Example 4. The apparatus of claim 1, the manifold comprising a retention element to automatically move the plunger to the second position when the retention element receives power.

Example 5. The apparatus of claim 4, the retention element is arranged to maintain the plunger in the second position when the retention element continually receives power.

Example 6. The apparatus of claim 4, wherein the retention mechanism is one of an electromagnet or a servo.

Example 7. The apparatus of claim 1, wherein the plunger includes a first seal positioned on a first side of the fluid flow channel and a second seal positioned on a second side of the fluid flow channel formed in the plunger to prevent leakage of the cooling fluid.

Example 8. The apparatus of claim 1, the manifold comprising a pin positioned within the housing to maintain the plunger in the second position.

Example 9. A system, comprising a plurality of racks, each rack including a plurality of nodes, each of the plurality of nodes including tubing configured to enable a flow of a cooling fluid to cool the node; and a manifold including a housing having an inlet for receiving a flow of the cooling fluid via tubing, one or more outlets for enabling the outflow of the cooling fluid via tubing, and a fluid flow passage for enabling the flow of the cooling fluid from the inlet to the one or more outlets, the manifold further including a plunger moveable between a first position and a second position, the plunger including a fluid flow channel, wherein in the first position, the fluid flow channel in the plunger is misaligned with the fluid flow passage in the housing so that the flow of the cooling fluid from the inlet to the one or more outlets is prevented; and in the second position, the fluid flow channel in the plunger is aligned with the fluid flow passage in the housing so that the flow of the cooling fluid from the inlet to the one or more outlets is permitted; wherein the plunger is configured to move to the first position automatically when electrical power to the manifold is terminated.

Example 10. The system of claim 9, wherein the manifold includes a biasing member for biasing the plunger to the first position.

Example 11. The system of claim 10, wherein the biasing member is a spring.

Example 12. The system of claim 10, wherein, when the manifold is energized, the plunger is moved to the second position.

Example 13. The system of claim 9, wherein the manifold includes a retention mechanism arranged and configured to maintain the plunger in the second position when the manifold is energized.

Example 14. The system of claim 13, wherein the retention mechanism is one of an electromagnet or a servo.

Example 15. The system of claim 9, wherein the plunger includes first and second seals position on either side of the fluid flow channel formed in the plunger to prevent leakage of the cooling fluid.

Example 16. The system of claim 9, wherein the plunger is configured to receive a pin to maintain the plunger in the second position.

Example 17. A method comprising receiving a flow of a cooling flow through a plurality of nodes for liquid cooling; detecting a leak of the cooling fluid; terminating electrical power to a manifold positioned within the flow of the cooling fluid; and moving a plunger of the manifold to prevent the flow of the cooling fluid.

Example 18. The method of claim 17, wherein the plunger is moveable between a first position and a second position, the plunger including a fluid flow channel; wherein, with electrical power supplied to the manifold, the plunger is maintained in the second position so that the flow of cooling fluid is permitted through the manifold; and, with electrical power terminated to the manifold, the plunger moves to the first position to prevent the flow of cooling fluid through the manifold.

Example 19. The method of claim 18, the manifold including a fluid flow channel in the plunger; wherein, in the first position, the fluid flow channel is misaligned with a fluid flow passage in the housing; and in the second position, the fluid flow channel in the plunger is aligned with the fluid flow passage.

Example 20. The method of claim 19, wherein upon terminating electrical power to the manifold, a retention mechanism releases the plunger causing the plunger to automatically move the plunger to the first position.

What is claimed is:

1. An apparatus, comprising:
a manifold for a node of a datacenter, the manifold comprising a housing and a plunger positioned within the housing, the housing comprising:
an inlet for receiving an inflow of a cooling fluid via tubing;
an outlet for enabling an outflow of the cooling fluid via tubing; and
a fluid flow passage for enabling the flow of the cooling fluid from the inlet to the outlet; and
the plunger including a fluid flow channel and a biasing member, the plunger moveable between a first position and a second position,
wherein:
in the first position, the fluid flow channel in the plunger is misaligned with the fluid flow passage in the housing to prevent the flow of the cooling fluid from the inlet to the outlet;
in the second position, the fluid flow channel in the plunger is aligned with the fluid flow passage in the housing to permit the flow of the cooling fluid from the inlet to the outlet; and
the biasing member automatically moves the plunger from the second position to the first position to prevent the flow of liquid upon a loss of power.

2. The apparatus of claim 1, wherein the biasing member biases the plunger to the first position.

3. The apparatus of claim 1, wherein the biasing member is a spring.

4. The apparatus of claim 1, the manifold comprising a retention element to automatically move the plunger to the second position when the retention element receives power.

5. The apparatus of claim 4, the retention element is arranged to maintain the plunger in the second position when the retention element continually receives power.

6. The apparatus of claim 4, wherein the retention mechanism is one of an electromagnet or a servo.

7. The apparatus of claim 1, wherein the plunger includes a first seal positioned on a first side of the fluid flow channel and a second seal positioned on a second side of the fluid flow channel formed in the plunger to prevent leakage of the cooling fluid.

8. The apparatus of claim 1, the manifold comprising a pin positioned within the housing to maintain the plunger in the second position.

9. A system, comprising:
a plurality of racks, each rack including a plurality of nodes, each of the plurality of nodes including tubing configured to enable a flow of a cooling fluid to cool the node; and
a manifold including a housing having an inlet for receiving a flow of the cooling fluid via tubing, one or more outlets for enabling the outflow of the cooling fluid via tubing, and a fluid flow passage for enabling the flow of the cooling fluid from the inlet to the one or more outlets, the manifold further including a plunger moveable between a first position and a second position, the plunger including a fluid flow channel, wherein:
in the first position, the fluid flow channel in the plunger is misaligned with the fluid flow passage in the housing so that the flow of the cooling fluid from the inlet to the one or more outlets is prevented; and
in the second position, the fluid flow channel in the plunger is aligned with the fluid flow passage in the housing so that the flow of the cooling fluid from the inlet to the one or more outlets is permitted;
wherein the plunger is configured to move to the first position automatically when electrical power to the manifold is terminated.

10. The system of claim 9, wherein the manifold includes a biasing member for biasing the plunger to the first position.

11. The system of claim 10, wherein the biasing member is a spring.

12. The system of claim 10, wherein, when the manifold is energized, the plunger is moved to the second position.

13. The system of claim 9, wherein the manifold includes a retention mechanism arranged and configured to maintain the plunger in the second position when the manifold is energized.

14. The system of claim 13, wherein the retention mechanism is one of an electromagnet or a servo.

15. The system of claim 9, wherein the plunger includes first and second seals position on either side of the fluid flow channel formed in the plunger to prevent leakage of the cooling fluid.

16. The system of claim 9, wherein the plunger is configured to receive a pin to maintain the plunger in the second position.

17. A method comprising:
receiving a flow of a cooling flow through a plurality of nodes for liquid cooling;
detecting a leak of the cooling fluid;
terminating electrical power to a manifold positioned within the flow of the cooling fluid; and
moving a plunger of the manifold to prevent the flow of the cooling fluid.

18. The method of claim 17, wherein the plunger is moveable between a first position and a second position, the plunger including a fluid flow channel;
wherein, with electrical power supplied to the manifold, the plunger is maintained in the second position so that the flow of cooling fluid is permitted through the manifold; and, with electrical power terminated to the manifold, the plunger moves to the first position to prevent the flow of cooling fluid through the manifold.

19. The method of claim 18, the manifold including a fluid flow channel in the plunger; wherein, in the first position, the fluid flow channel is misaligned with a fluid flow passage in the housing; and in the second position, the fluid flow channel in the plunger is aligned with the fluid flow passage.

20. The method of claim 19, wherein upon terminating electrical power to the manifold, a retention mechanism releases the plunger causing the plunger to automatically move the plunger to the first position.
